(19) United States
(12) Patent Application Publication
(10) Pub. No.: US 2012/0274315 A1
(43) Pub. Date: Nov. 1, 2012

(54) Rotation Angle Measurement Assembly

(76) Inventors: Michael L. Rhodes, Richfield, MN (US); Ronald G. Landman, Fargo, ND (US)

(21) Appl. No.: 13/096,100

(22) Filed: Apr. 28, 2011

(51) Int. Cl. G01R 35/00; G01B 7/30

(52) U.S. Cl. 324/202; 324/207.25

(57) ABSTRACT

An assembly is provided comprising a member having a graduated edge that varies in radius with respect to an axis, and a sensor adjacent to the graduated edge, the member and the sensor are capable of rotating relative to one another. The sensor provides a signal level proportional to a distance between the sensor and the graduated edge, and the distance, between the sensor and the graduated edge, is indicative of a rotation angle of the member relative to the sensor.

### FIELD OF THE DISCLOSURE

The present disclosure relates to a rotation angle measurement assembly.

### BACKGROUND OF THE DISCLOSURE

At least some, existing solutions for measuring a rotation angle of a member required attachment of a sensor on the member. Such a sensor was typically an encoder that rotated with the member, and the sensor would register a specific number of pulses for each degree of rotation. Attachment of the sensor to the member was often times difficult due to, for example, space limitations. Further attachment of the sensor was difficult, because a wire, which attaches to the sensor, could become twisted and tangled as the member rotates. In addition, under such conditions, the wire could brake as the result of fatigue or from being stretched too far. To make matters worse, existing solutions often times use complicated and expensive sensors, processing solutions, and calibration procedures. Accordingly, what is needed in the art is a rotation angle measurement assembly that overcomes the aforementioned issues.

### SUMMARY OF THE DISCLOSURE

According to the present disclosure, a rotation angle measurement assembly is provided. The assembly comprises a member having a graduated edge that varies in radius with respect to an axis. The assembly further comprises a sensor adjacent to the graduated edge. The sensor provides a signal level proportional to a distance between the sensor and the graduated edge, and the distance, between the sensor and the graduated edge, is indicative of a rotation angle of the member relative to the sensor.

Additionally, according to the present disclosure is a method for determining the rotation angle of the member. The method comprises the steps providing the member capable of rotation about the axis with the graduated edge that varies in radius with respect to the axis; providing the sensor adjacent to the graduate edge; using the sensor to provide the signal level proportional to a distance between the sensor and the graduated edge; and determining the rotation angle of the member relative to the sensor via a predefined relationship between the signal level and the rotation angle.

The above and other features will become apparent from the following description and the attached drawings.

### BRIEF DESCRIPTION OF THE DRAWINGS

The detailed description of the drawings refers to the accompanying figures in which:

FIG. 1 is a block diagram of a first rotation angle measurement assembly;

FIG. 2 is a diagram of the first assembly comprising a first member and a sensor, the first member having a radially discontinuous edge;

FIG. 3 is a graph of a signal level of the sensor versus a rotation angle of the first member;

FIG. 4 is a diagram of a second rotation angle measurement assembly comprising a second member and the sensor, the second member having a plurality of radially discontinuous edges;

FIG. 5 is a graph of a signal level of the sensor versus a rotation angle of the second member;

FIG. 6 is a perspective view of the first assembly further comprising a wheel assembly, and;

FIG. 7 is a flow chart of a method for determining the rotation angle of the member.

### DETAILED DESCRIPTION OF THE DRAWINGS

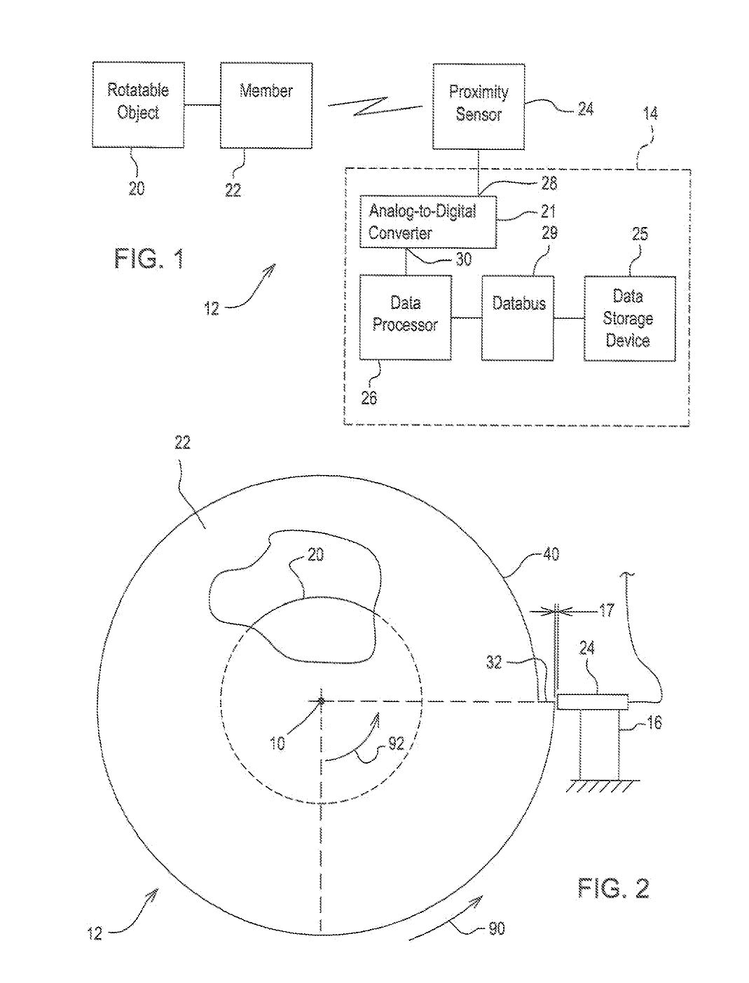

Referring to FIG. 1, there is shown a block diagram of a first rotation angle measurement assembly 12. The first assembly 12 comprises a first member 22 having a graduated edge 40 that varies in radius with respect to an axis 10. Additionally, the first assembly 12 comprises a sensor 24 adjacent to the graduated edge 40. This arrangement allows the sensor 24 to provide a signal level proportional to a distance 17, between the sensor 24 and the graduated edge 40, wherein this distance 17 is indicative of the rotation angle 92 of the first member 22 relative to the sensor 24. FIG. 2 is a diagram of the first assembly 12, and it illustrates, among other things, an exemplary embodiment of the arrangement of the first member 22 relative to the sensor 24.

The first member 22 may further comprise a radially discontinuous edge 32 that distinctly varies in radius with respect to the axis 10. When viewing the first member 22, in a counterclockwise direction, the radius with respect to the axis 10 continuously increases until reaching the discontinuous edge 32. At the discontinuous edge 32, the radius, as measured from the axis 10, decreases. The discontinuous edge 32 may take a number of different forms, including, for example, a notch or a step. The first member 22 may be mechanically linked—either directly or indirectly—to a rotatable object 20. Exemplarily, the rotatable object 20 is a shaft, but it may be any type of object that rotates.

Exemplarily, the sensor 24 may be an inductive sensor, a capacitive sensor, an optical sensor, a linear variable differential transformer, or any other sensor capable of providing a signal level proportional to the distance 17 between the sensor 24 and the graduated edge 40. The sensor 24 may be supported by a fixed supporting structure 16, such as, for example, a clamp (not shown), a screw (not shown), an adhesive (not shown), or any other securing mechanism for the sensor 24.

In the illustrated embodiment, the sensor 24 is fixed, but the first member 22, in contrast, rotates about axis 10. In other embodiments, the sensor 24 may be free to rotate about the axis 10, while the first member 22 may be fixed. In such an arrangement, the sensor 24 and the first member 22 rotate relative to one another, so the sensor 24 provides the signal level proportional to the distance 17 between the sensor 24 and the graduated edge 40, which is ultimately indicative of the rotation angle 92 of the first member 22 relative to the sensor 24.

Also shown in the illustrated embodiment, the graduated edge 40 is an outer edge. However, the graduated edge 40 may also be in inner edge. Here, yet again, the sensor 24 would provide the signal level proportional to the distance 17 between the sensor 24 and the graduated edge 40, wherein the signal level is indicative of the rotation angle 92 of the first member 22 relative to the sensor 24.

The first assembly 12 may further comprise an analog-to-digital converter 21 having an input 28 and an output 30. The input 28 of the analog-to-digital converter 21 may be in communication with the sensor 24, and the output 30 may be in communication with a data processor 26. A data storage device 25 may be in communication with the data processor 26 via a databus 29. The data storage device 25 for storing data related to a predefined relationship between the signal level and the rotation angle 92 of the first member 22. Exemplarily, the data storage device 25 may be read-only-memory; a hard drive; a removable medium, such as a flash card; or any other medium capable of storing the predetermined relationship data. The data storage device 25 may be a separate component, or may be integrated into the data processor 26.

The analog-to-digital converter 21, data processor 26, and data storage device 25 may communicate via a databus 29, and these components may all be part of an electronic data processing system 14. The electronic data processing system 14 may further comprise a general purpose computer (not shown), a precision agricultural display (not shown), and/or another any other object capable of receiving and processing the signal level from the sensor 24.

The sensor 24 may directly communicate the signal level as a digital input to the data processor 26, or the sensor 24 may communicate the signal level as an analog signal. If the signal is an analog signal, then the analog-to-digital converter 21 may be used to convert it to a digital signal. The analog-to-digital converter 21 may be a separate component, or it may be integrated into the data processor 26.

The data processor 26 may be used for converting and processing the signal level, from the sensor 24, and determining the rotation angle 92 of the first member 22. Such processing is based on a predetermined relationship between the distance 17 and the rotation angle 92 of the first member 22. Furthermore, the data processor 26 may comprise a microprocessor (not shown), a precision farming display (not shown), a programmable logic array (not shown), a field programmable gate array (not shown), a general purpose computer (not shown), or other similar device capable of receiving and processing data.

In one embodiment, the predetermined relationship comprises a one-to-one relationship between the distance 17, as measured by the sensor 24, and the rotation angle 92. Thus, the predetermined relationship between the signal level and the rotation angle 92 of the first member 22 may be known via a look-up table, or a database stored on the data processor 26, or the data storage device 25. In another embodiment, the relationship between the signal level and the rotation angle 92 of the first member 22 may be described by a mathematical expression. Exemplarily, the relationship may be defined via a linear equation or a quadratic equation. In such an embodiment, the sensor 24 outputs the signal level to the data processor 26. The data processor 26, then, calculates the rotation angle 92 of the first member 22 via the signal level and the predetermined mathematical relationship.

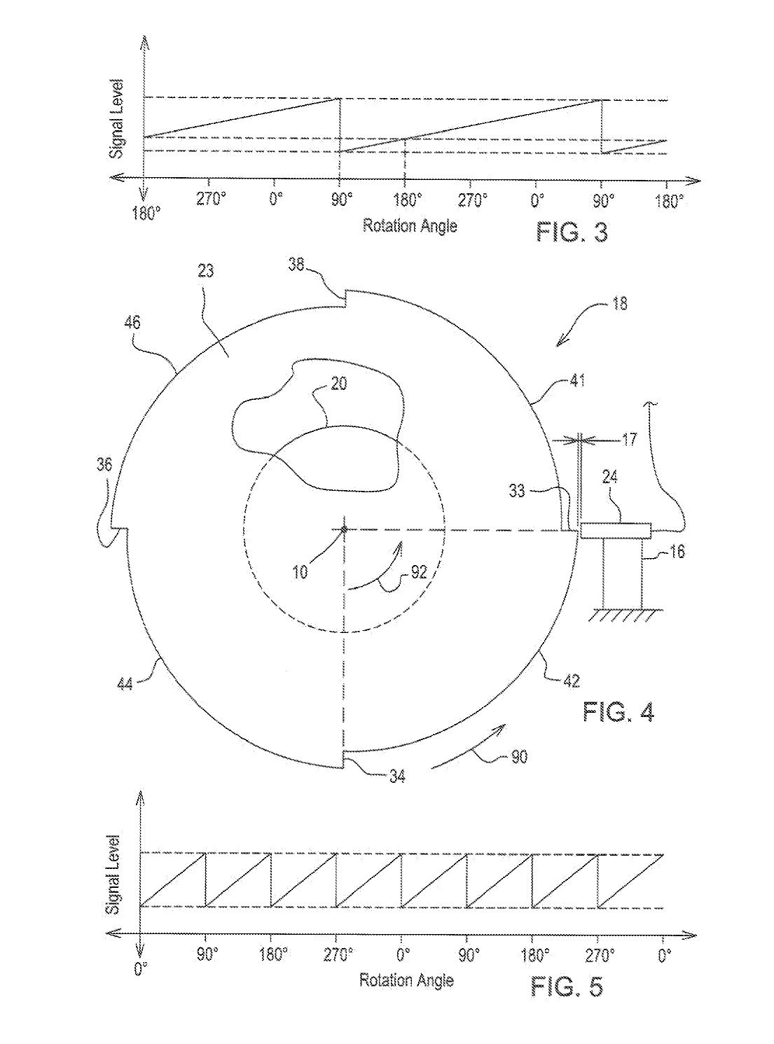

Referring to FIG. 3, there is shown a graph of a signal output of the first assembly 12, as illustrated in FIG. 2, versus a rotation angle 92 of the first member 22. Here, the vertical axis represents the signal level, and the horizontal axis represents the rotation angle 92 of the first member 22. In this embodiment, the first member 22 is aligned such that the discontinuous edge 32 passes the sensor 24 when the rotation angle 92 of the first member 22 is 90°. As the first member 22 rotates counterclockwise, about the axis 10, in the direction of arrow 90, the distance 17 between the graduated edge 40 and the sensor 24 increases. This causes the signal level to steadily change until the discontinuous edge 32 passes the sensor 24, wherein the signal level abruptly changes. This abrupt signal level change indicates that the discontinuous edge 32 has passed the sensor 24, which also indicates the rotation angle 92 of the first member 22. Whether the signal level abruptly changes depends on the type of sensor 24 and the shape of the first member 22 or, more particularly, the shape of the discontinuous edge 32, and also depends on the direction that the first member 22 is rotating. In the embodiment shown, the first member 22 rotates counterclockwise, in the direction of arrow 90, but the first member 22 may also rotate clockwise or both clockwise and counterclockwise, depending on the application.

The orientation of the discontinuous edge 32 allows for self-calibration of the first assembly 12, which may compensate for vibration and thermal expansion. Self-calibration is relatively easy, because the discontinuous edge 32 can be aligned to correspond with a known rotation angle of the first member 22. For example, in the embodiment shown, in FIG. 3, the discontinuous edge 32 corresponds to the rotation angle 92 of 90°. Therefore, as the discontinuous edge 32 passes the sensor 24, the signal level abruptly changes from the highest signal level to the lowest signal level. The orientation of the discontinuous edge about the first member 22 does not matter, as long as the orientation is known.

As shown in FIG. 3, the signal level rises linearly with respect to the rotation angle 92, but in other embodiments, the signal level may fall linearly or rise and fall non-linearly. Ultimately, the rise and fall of the signal level is related to the type of sensor 24 and the shape of the first member 22. Because the first member 22 can take various shapes, the signal level can take various shapes too. A linear profile may be desirable for its simplicity, but a non-linear profile may also be desirable, because it may emphasize particular rotation angles.

Referring to FIG. 4, there is shown a diagram of a second rotation angle measurement assembly 18 comprising a second member 23 having at least two radially discontinuous edges. A difference between the first assembly 12 and the second assembly 18 is the second member 23. But, the second assembly 18 has several components that are similar in structure and function as the first assembly 12, as indicated by the use of identical reference numbers where applicable.

Second member 23 may have first, second, third, and fourth graduated edges 41, 42, 44, 46, and the second member 23 may further have first, second, third, and fourth radially discontinuous edge 33, 34, 36, 38. In this embodiment, the discontinuous edges 33, 34, 36, 38 are spaced equidistant about the second member 23, but other spacings also fall under the scope of the claims. Exemplarily, the discontinuous edges 33, 34, 36, and 38 are steps, but they may take other shapes as well. Additionally, the second member 23 may have at least two and, theoretically, up to infinity graduated edges and discontinuous edges.

The second assembly 18 operates in the same way as the first assembly 12. One difference, however, is that the four discontinuous edges 33, 34, 36, 38 provide four distinct self-calibration points, rather than just one. Therefore, in this embodiment, even if the second member 23 only rotates 270°, three discontinuous edges would pass in front of the sensor 24.

Referring to FIG. 5, there is shown a graph of the signal level of the sensor 24 versus a rotation angle of the second member 23. The vertical axis represents the signal level, and the horizontal axis represents the rotation angle 92 of the first member 22. In this embodiment, the second member 23 is aligned such that the first discontinuous edge 33 passes the sensor 24 when the rotation angle 92 of the second member is 90°. Further, the second, third, and fourth discontinuous edge 34, 36, and 38 pass the sensor 24 at 180°, 270°, and 0° respectively. It may be advantageous to design the discontinuous edges 33, 34, 36, 38 such that they are all distinctly shaped and, thus, provide distinct signal levels. By designing the discontinuous edges 33, 34, 36, 38, in this way, it may be easier to identify whether, for example, the first discontinuous edge 33 is directly in front of the sensor 24, or whether the second discontinuous edge 34 is front of the sensor 24.

The shape of the second member 23 or, more particularly, the shape formed by the discontinuous edges 33, 34, 36, and 38 allows for self-calibration of the second assembly 18. Self calibration is possible at all four discontinuous edges 33, 34, 36, and 38, because they can be aligned to correspond with known rotation angles of the second member 23. As stated above, the first discontinuous edge 33 passes the sensor 24 when the rotation angle 92 of the second member is 90°. Therefore, in the embodiment shown in FIG. 5, as the first discontinuous edge 33 passes the sensor 24, the signal level abruptly changes. Likewise, the signal level abruptly changes as the second, third and fourth discontinuous edges 34, 36, 38 pass the sensor 24. Ultimately, the angular placement of the discontinuous edges 33, 34, 36, 38 about the second member 23 does not matter. All that matters, with respect to self-calibration, is that the orientation of the discontinuous edges 33, 34, 36, 38 is known.

In this particular embodiment, the signal level rises linearly with respect to the rotation angle 92, but in other embodiments, the signal level may not rise linearly. Ultimately, the rise and fall of the signal level is related to the type of sensor 24 and the shape of the second member 23. The second assembly 18 may also be designed such that the second member 23 rotates clockwise or such that second member 23 rotates both clockwise and counterclockwise. Further yet, the second member 23 may be designed such that radius of the graduated edges 41, 42, 44, 46 become larger when viewed in a counterclockwise manner (see FIG. 4), or alternatively, the second member 23 may be designed such that the radius of the graduated edges 41, 42, 44, 46 become larger when viewed in a clockwise manner (not shown).

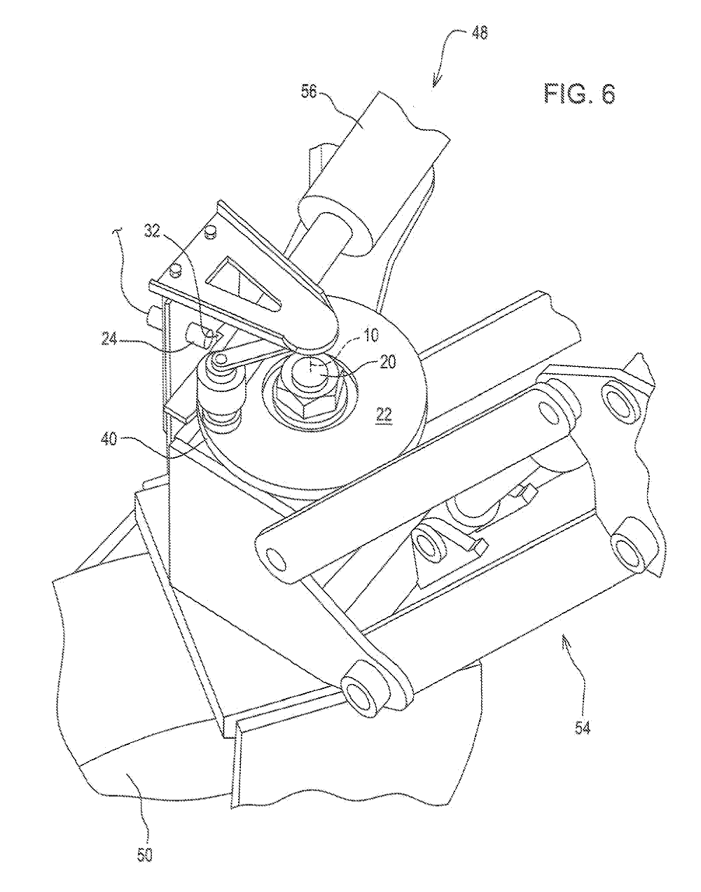

FIG. 6 is a perspective view of the first assembly 12 further comprising a wheel assembly 48 mechanically coupled to the first member 22. In this embodiment, the wheel assembly 48 comprises a wheel 50 supported by the rotatable object 20. The rotatable object 20, which is in the form of a steering shaft, works in combination with a support linkage 54 and a hydraulic arm 56 for use on, exemplarily, an agricultural implement (not shown). The wheel assembly 48 may also be known as a lift assist assembly. As the support linkage 54 extends, the wheel 50 contacts the ground and thereby, along with the help of a hitch (not shown), raises the agricultural implement (not shown). Alternatively, as the support linkage 54 retracts, the wheel 50 may be pulled off of the ground, wherein the agricultural implement (not shown) supports its own weight by other means (not shown).

The wheel 50 may be capable of rotating more than 360°. To avoid damage to, for example, agricultural fields, it may be desirable to steer the wheel 50 via the hydraulic arm 56. In this arrangement, the sensor 24 provides a signal level proportional to the distance 17, between the sensor 24 and the graduated edge 40, wherein this distance 17 is indicative of a rotation angle of the first member 22 and, therefore, the wheel 50. It may be desirable to determine the rotation angle of wheel 50, so that the rotation angle can be adjusted, via the hydraulic arm 56, to one that does the least amount of damage to the agricultural field.

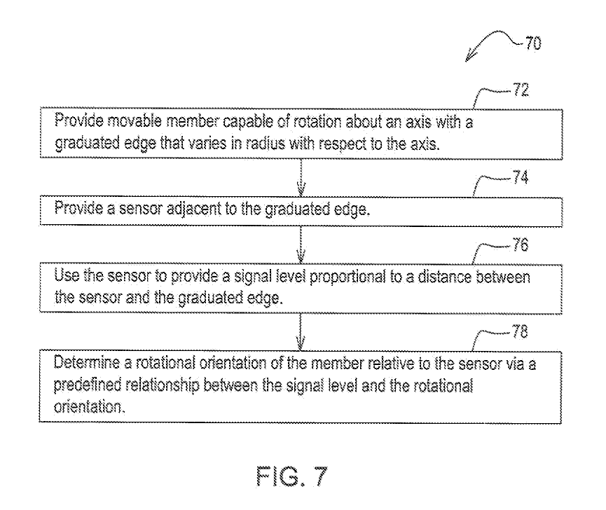

Referring to FIG. 7, there is shown a method 70 for determining the rotation angle 92 of the first member 22. The method 70 would work with either the first assembly 12 or the second assembly 18. However, for simplicity, the method 70 will only be described using the first assembly 12.

Act 72 of method 70 is to provide the first member 22, wherein the first member 22 is capable of rotation about an axis 10, and the first member 22 has a graduated edge 40 that varies in radius with respect to the axis 10. Act 74 of method 70 is to provide the sensor 24 adjacent to the graduated edge 40. Act 76 of method 70 is to use the sensor 24 to provide a signal level proportional to the distance 17 between the sensor 24 and the graduated edge 40. Act 78 of the method 70 is to determine the rotation angle 92 of the first member 22 relative to the sensor 24 via a predefined relationship between the signal level and the rotation angle 92 of the first member 22. A further act of method 70 may be to provide the data processor 26 in communication with the sensor 24, wherein the determining is performed via the data processor 26.

A further act of method 70 may be to provide the discontinuous edge 32 that distinctly varies in radius with respect to the axis 10. A further act of method 70 may be to detect an abrupt signal level change associated with the passing of the discontinuous edge 32 past the sensor 24, wherein the abrupt signal level change, at the discontinuous edge 32, identifies a known rotation angle of the first member 22. Further yet, an act of method 70 may be to calibrate the predefined relationship, between the signal level and the rotation angle 92 of the first member 22 based on the abrupt signal level change.

While the disclosure has been illustrated and described in detail in the drawings and foregoing description, such illustration and description is to be considered as exemplary and not restrictive in character, it being understood that illustrative embodiments have been shown and described and that all changes and modifications that come within the spirit of the disclosure are desired to be protected. Alternative embodiments of the present disclosure may not include all of the features described yet still benefit from at least some of the advantages of such features. Those of ordinary skill in the art may readily devise their own implementations that incorporate one or more of the features of the present disclosure and fall within the spirit and scope of the present disclosure as defined by the appended claims.

What is claimed is:

1. A rotation angle measurement assembly comprising:
a member having a graduated edge that varies in radius with respect to an axis; and
a sensor adjacent to the graduated edge, the member and the sensor are capable of rotating relative to one another, the sensor provides a signal level proportional to a distance between the sensor and the graduated edge, and the distance between the sensor and the graduated edge is indicative of a rotation angle of the member relative to the sensor.

2. The rotation angle measurement assembly of claim 1, further comprising:
an analog-to-digital converter having an input and an output, the input of the analog-to-digital converter is in communication with the sensor;
a data processor in communication with the output; and
a data storage device in communication with the data processor for storing data related to a predefined relationship between the signal level and the rotation angle of the member relative to the sensor.

3. The rotation angle measurement assembly of claim 1, further comprising a wheel assembly mechanically coupled to the member, and the wheel assembly rotates with respect to the sensor.

4. The rotation angle measurement assembly of claim 1, further comprising a steering shaft mechanically coupled to the member for rotation, and the steering shaft rotates with respect to the sensor.

5. The rotation angle measurement assembly of claim 1, wherein the sensor is fixed.

6. The rotation angle measurement assembly of claim 1, wherein the graduated edge is an outer edge.

7. The rotation angle measurement assembly of claim 1, wherein the sensor is one of an inductive sensor and a capacitive sensor.

8. The rotation angle measurement assembly of claim 1, wherein the sensor is a capacitive sensor.

9. The rotation angle measurement assembly of claim 1, wherein the member further comprises a radially discontinuous edge that distinctly varies in radius with respect to the axis, and the graduated edge gradually vanes in radius with respect to the axis.

10. The rotation angle measurement assembly of claim 9, wherein the radially discontinuous edge is a step.

11. The rotation angle measurement assembly of claim 1, wherein the member comprises at least two radially discontinuous edges that distinctly vary in radius with respect to the axis.

12. The rotation angle measurement assembly of claim 11, wherein the at least two radially discontinuous edges are spaced equidistant about the member.

13. The rotation angle measurement assembly of claim 12, wherein the at least two radially discontinuous edges are steps.

14. A method for determining a rotation angle of a member, the method comprising:
providing the member capable of rotation about an axis with a graduated edge that varies in radius with respect to the axis;
providing a sensor adjacent to the graduated edge;
using the sensor to provide a signal level proportional to a distance between the sensor and the graduated edge; and
determining a rotation angle of the member relative to the sensor via a predefined relationship between the signal level and the rotation angle.

15. The method for determining a v of claim 14, further comprising the step of providing a data processor in communication with the sensor, and the determining is performed via the data processor.

16. The method for determining a rotation angle of claim 14, wherein the sensor is a capacitive sensor.

17. The method for determining a rotation angle of claim 14, wherein the sensor is an inductive sensor.

18. The method for determining a rotation angle of claim 14, wherein the predefined relationship, between the signal level and the rotation angle, is determined via one of a look-up table, a database, a linear equation, a quadratic equation, and a function.

19. The method for determining a rotation angle of claim 14, wherein the member comprises a radially discontinuous edge that distinctly varies in radius with respect to the axis, and the graduated edge gradually varies in radius with respect to the axis.

20. The method for determining a rotation angle of claim 19, further comprising the steps of:
detecting an abrupt signal level change associated with a passing of the radially discontinuous edge past the sensor, the abrupt signal level change at the radially discontinuous edge identifies a known rotation angle of the member; and
calibrating the predefined relationship, between the signal level and the rotation angle of the member, based on the abrupt signal level change.
